(19) United States
(12) Patent Application Publication
(10) Pub. No.: US 2010/0302842 A1
(43) Pub. Date: Dec. 2, 2010

(54) SEMICONDUCTOR MEMORY DEVICE, MANUFACTURING METHOD THEREOF, DATA PROCESSING SYSTEM, AND DATA PROCESSING DEVICE

(75) Inventors: Tsuyoshi KAWAGOE, Chuo-ku (JP); Isamu Asano, Chuo-ku (JP)

Correspondence Address: SUGHRUE MION, PLLC, 2100 PENNSYLVANIA AVENUE, N.W., SUITE 800, WASHINGTON, DC, 20037, US

(73) Assignee: ELPIDA MEMORY, INC., Tokyo (JP)

(21) Appl. No.: 12/792,296

(22) Filed: Jun. 2, 2010

(30) Foreign Application Priority Data
Jun. 2, 2009 (JP) 2009-132701

(51) Int. Cl. G11C 11/00; H01L 45/00; H01L 21/04

(52) U.S. Cl. 365/163; 257/2; 438/510; 257/E45.001; 365/148; 257/E21.09; 365/200

(57) ABSTRACT

A semiconductor memory device includes: first and second impurity diffusion layers that form a part of a semiconductor substrate, each of the impurity diffusion layers function as one and the other of an anode and a cathode, respectively of a pn-junction diode; a recording layer connected to the second impurity diffusion layer; and a cylindrical sidewall insulation film provided on the first impurity diffusion layer. At least a part of the second diffusion layer and at least a part of the recording layer are formed in a region surrounded by a sidewall insulation film. According to the present invention, because a pillar-shaped pn-junction diode and the recording layer are formed in a self-aligned manner, the degree of integration of a semiconductor memory device can be increased. Further, because a silicon pillar is a part of the semiconductor substrate, a leakage current attributable to a crystal defect can be reduced.

### BACKGROUND OF THE INVENTION

1. Field of the Invention

The present invention relates to a semiconductor memory device and a manufacturing method thereof, and more particularly relates to a semiconductor memory device using pn-j unction diodes as a selection element and a manufacturing method of the semiconductor memory device. The present invention also relates to a data processing system and a data processing device, which include memory cells using pn-junction diodes.

2. Description of Related Art

Most of semiconductor memory devices in practical application at present are configured such that a number of memory elements are arranged in a matrix in an X direction and a Y direction. To access a specific one of these memory elements, any one of plural selection lines (word lines) arranged in the X direction is activated to make it possible to access the memory element via a signal line (a bit line) arranged in the Y direction. More specifically, memory elements and selection elements are connected in series between word lines and bit lines, and access to a desired memory element via a bit line becomes possible by activating any one of the word lines.

As explained above, a selection element to access a desired memory element is essential in a semiconductor memory device having memory elements arranged in a matrix. MOS transistors are used as selection elements in many semiconductor memory devices such as a DRAM (Dynamic Random Access Memory). When a MOS transistor is used as a selection element, a memory element and a bit line can be connected to or disconnected from each other by controlling a voltage of a word line. Therefore, the use of a MOS transistor as a selection element is particularly suitable in a voltage-sensing semiconductor memory device such as a DRAM.

However, when the degree of integration of a device becomes higher, an occupied area per one selection element becomes small. Therefore, there is a problem that an ON current of a selection element is reduced. To solve this problem, there has been an attempt to increase an ON current per unit area by setting a MOS transistor for a selection element in a three-dimensional structure. However, a manufacturing process of a MOS transistor in a three-dimensional structure is very complex, and a substantial increase in the ON current cannot be expected. Accordingly, in recent years, there have been many proposals of a semiconductor memory device using diodes instead of MOS transistors as selection elements. When diodes are used as selection elements, an ON current per unit area substantially increases as compared with a case when MOS transistors are used. Therefore, the use of diodes as selection elements is suitable for high integration semiconductor memory devices.

However, when diodes are used as selection elements, these diodes are switched by controlling a relative potential difference between a potential in a word line and a potential in a bit line. Therefore, the use of diodes as selection elements is not suitable for a voltage-sensing semiconductor memory device such as a DRAM, and is suitable for a current-sensing semiconductor memory device.

A PRAM (Phase-change Random Access Memory) is known as a current-sensing semiconductor memory device. The PRAM is a semiconductor memory device using a phase change compound as memory elements, and stores information based on a difference between electric resistances corresponding to a phase state of the phase change compound. Specifically, when a chalcogenide compound is used as a phase change compound, an electric resistance becomes relatively low in a crystal phase, and an electric resistance becomes relatively high in an amorphous phase. Therefore, stored data can be read out as the electric resistance of a phase change compound is detected by passing a read current. Regarding data writing, a phase of a phase change compound can be changed to a crystal phase when the phase change compound is heated at or higher than a crystallization temperature and lower than a melting point during a certain period of time or more by passing a write current. On the other hand, the phase of the phase change compound can be changed to an amorphous phase when the phase change compound is heated at or higher than a melting point by passing a write current and is rapidly cooled thereafter.

A PRAM described in Japanese Patent Application Publication No. 2005-536052 and in Japanese Patent Application Laid-open No. 2008-311666 is known as a PRAM using diodes as its selection elements.

However, according to the PRAM described in the patent documents mentioned above, a connection between a pillar-shaped pn-junction diode and a recording layer containing a chalcogenide compound is performed by alignment using a photolithography method. Therefore, a misalignment unavoidably occurs in positions on a plane. Accordingly, considering the misalignment, it is essential to secure a margin for a formation pitch of the pn-junction diode. This becomes a hindrance in increasing the degree of integration.

According to the PRAM described in Japanese Patent Application Laid-open No. 2008-311666, pillar-shaped pn-junction diodes are formed by a selective epitaxial method. Therefore, many crystal defects occur in silicon pillars, and these defects become a cause of increasing a leakage current. A silicon growth by the selective epitaxial method does not necessarily proceed uniformly on the plane, and has a large variation in manufacturing. Further, when the degree of integration becomes very high, the speed of silicon growth by the selective epitaxial method becomes slow, and the growth does not proceed in some cases.

The above problems occur in not only PRAMs but also in other semiconductor memory devices using pillar-shaped pn-junction diodes as selection elements.

### SUMMARY

In one embodiment, there is provided a semiconductor memory device comprising: a silicon pillar that projects to a perpendicular direction that is substantially perpendicular to a main surface of a semiconductor substrate; a diode having first and second impurity diffusion layers which form pn-junction, the first and second impurity diffusion layers being arranged in the perpendicular direction, at least one of the first and second impurity diffusion layers being provided in the silicon pillar; a cylindrical insulation film that surrounds a side surface of the silicon pillar and projects to the perpendicular direction, a top end of the cylindrical insulation film is higher than that of the silicon pillar; and a memory element electrically connected to the first impurity diffusion layer in a surrounded region that is surrounded by the cylindrical insulation film.

In another embodiment, there is provided a manufacturing method of a semiconductor memory device, comprising: forming a diode having a pn-junction by forming a first impurity diffusion layer in a semiconductor substrate and forming a second impurity diffusion layer at a lower part of the first impurity diffusion layer, thereby the first and second impurity diffusion layers are arranged in a direction perpendicular to a main surface of the semiconductor substrate; patterning the first impurity diffusion layer using a hard mask to form a silicon pillar; forming a sidewall insulation film on a side surface of the silicon pillar and the hard mask; removing the hard mask to form a cavity in a region surrounded by the sidewall insulation film; and forming at least a part of the memory element in the cavity.

As explained above, according to the present invention, the pillar-shaped pn-j unction diodes and the memory elements are formed in a self-aligned manner. Therefore, a formation pitch of the pn-j unction diodes can be made small. As a result, the degree of integration can be increased more than a conventional level. Further, because the pillar-shaped pn-junction diodes are constituted by a part of the semiconductor substrate, various problems attributable to the use of the selective epitaxial method do not occur. As a result, it is possible to provide a semiconductor memory device having less leakage current, less variation in manufacturing, and a high degree of integration.

### DETAILED DESCRIPTION OF THE EMBODIMENTS

The above features and advantages of the present invention will be more apparent from the following description of certain preferred embodiments taken in conjunction with the accompanying drawings, in which:

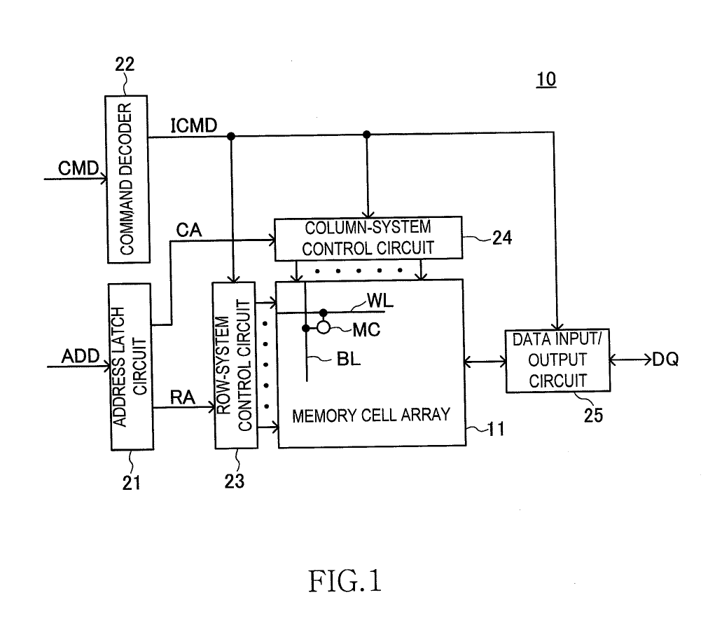

FIG. 1 is a block diagram of a semiconductor memory device 10 according to an embodiment of the present invention;

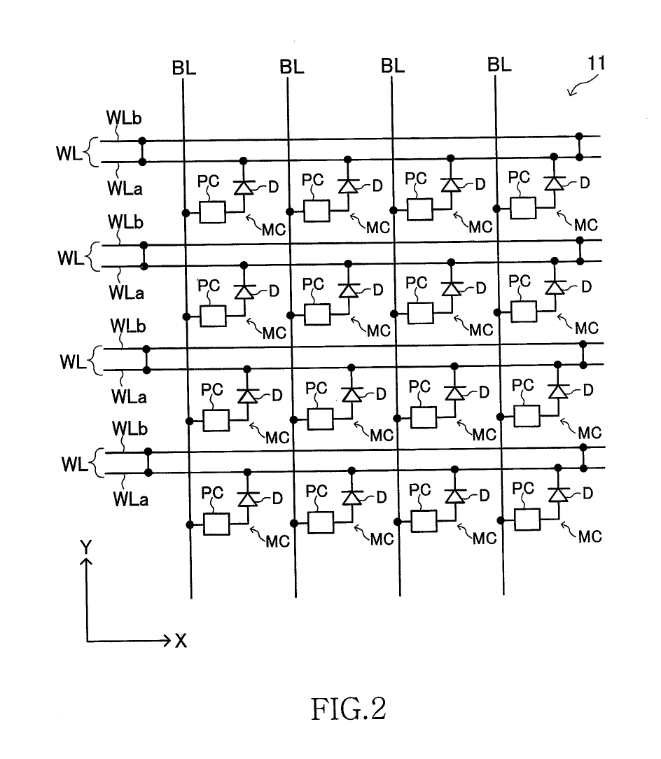

FIG. 2 is a circuit diagram showing a part of the memory cell array 11 in detail;

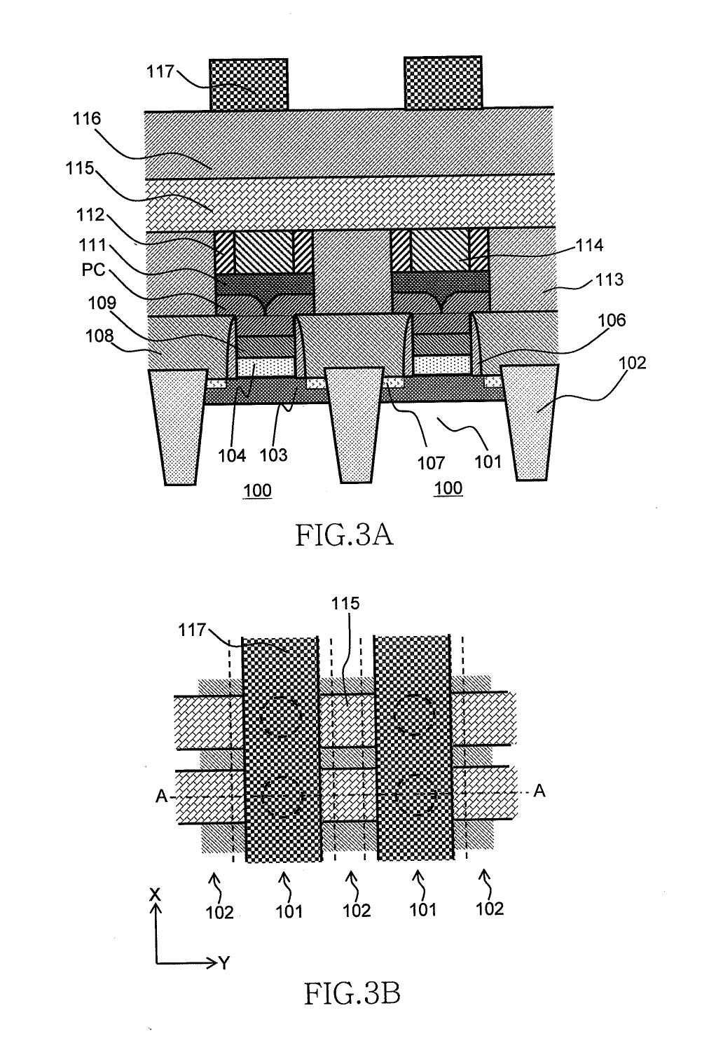

FIGS. 3A and 3B show a device configuration of the memory cell MC, where FIG. 3A shows a cross-sectional view, and FIG. 3B shows a plan view;

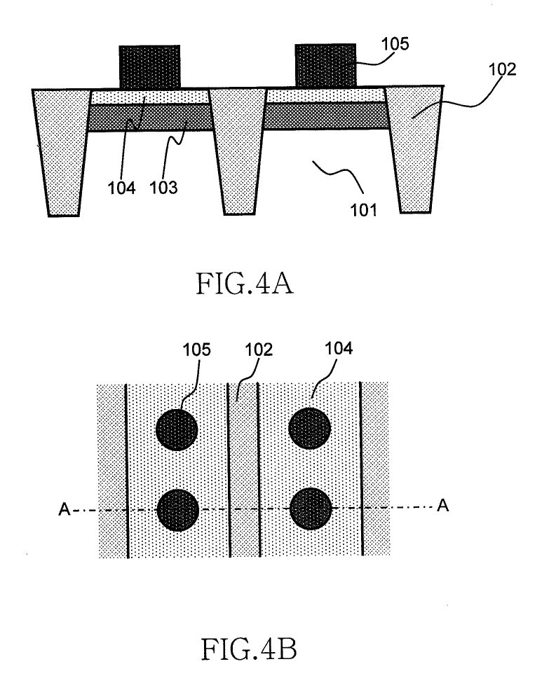

FIGS. 4A and 4B show a view showing a process (formation of a hard mask 105) in the manufacturing processes of the semiconductor memory device 10, where FIG. 4A shows a cross-sectional view, and FIG. 4B shows a plan view;

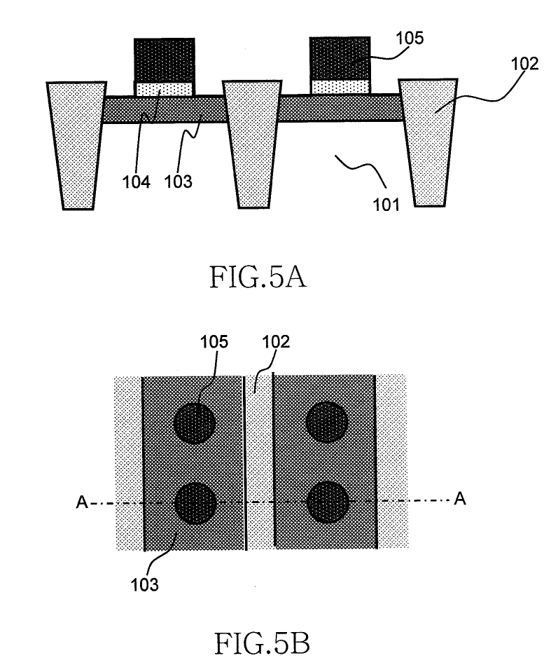

FIGS. 5A and 5B show a view showing a process (etching of p-type impurity diffusion layer 104) in the manufacturing processes of the semiconductor memory device 10, where FIG. 5A shows a cross-sectional view, and FIG. 5B shows a plan view;

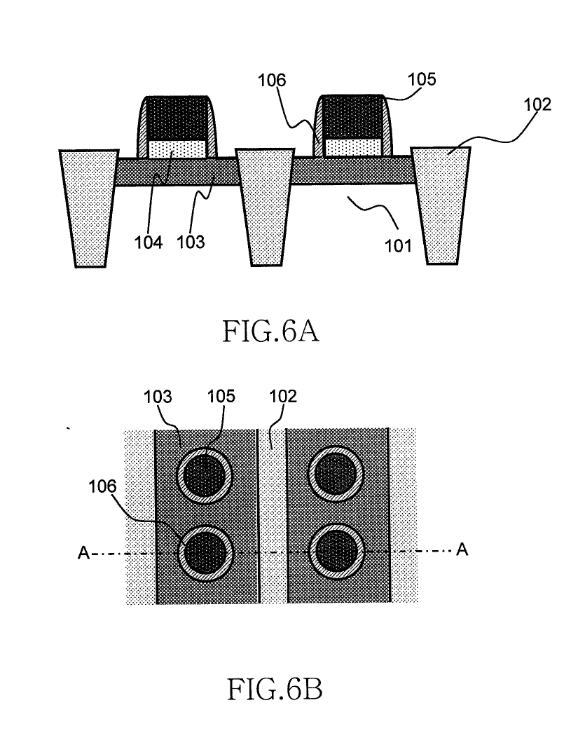

FIGS. 6A and 6B show a view showing a process (formation of a sidewall insulation film) in the manufacturing processes of the semiconductor memory device 10, where FIG. 6A shows a cross-sectional view, and FIG. 6B shows a plan view;

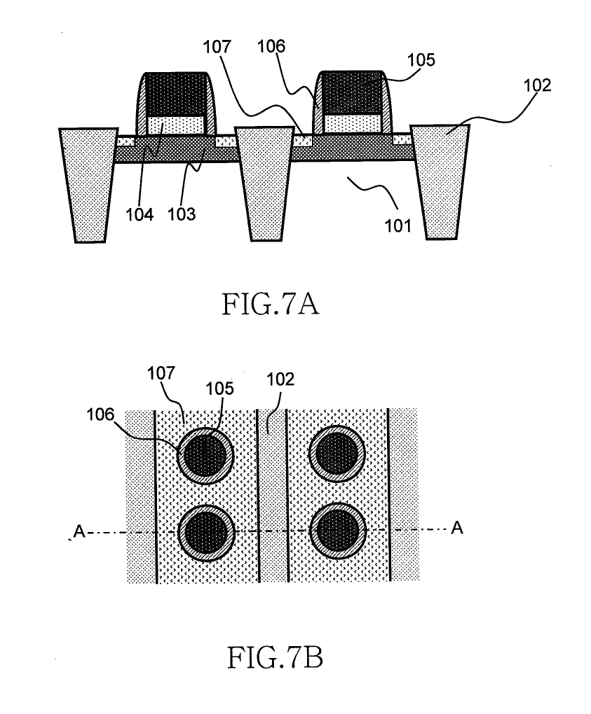

FIGS. 7A and 7B show a view showing a process (formation of a metal silicide layer 107) in the manufacturing processes of the semiconductor memory device 10, where FIG. 7A shows a cross-sectional view, and FIG. 713 shows a plan view;

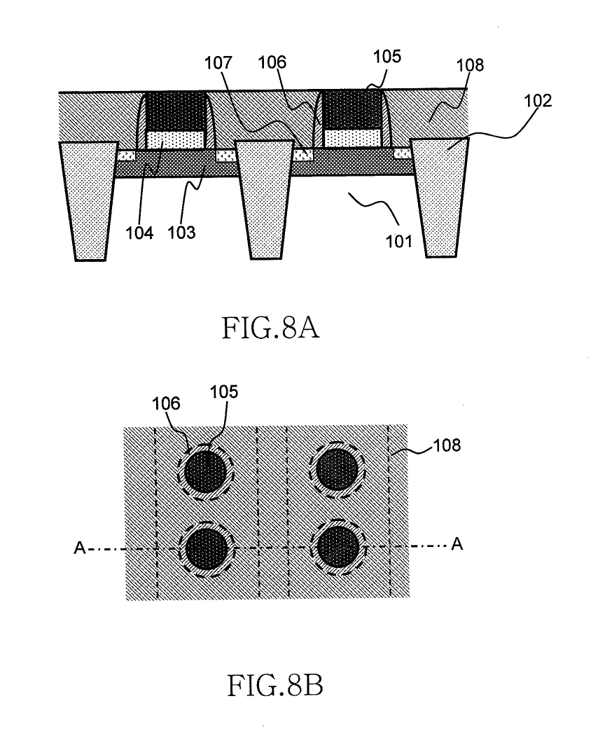

FIGS. 8A and 8B show a view showing a process (formation of interlayer insulation film 108) in the manufacturing processes of the semiconductor memory device 10, where FIG. 8A shows a cross-sectional view, and FIG. 8B shows a plan view;

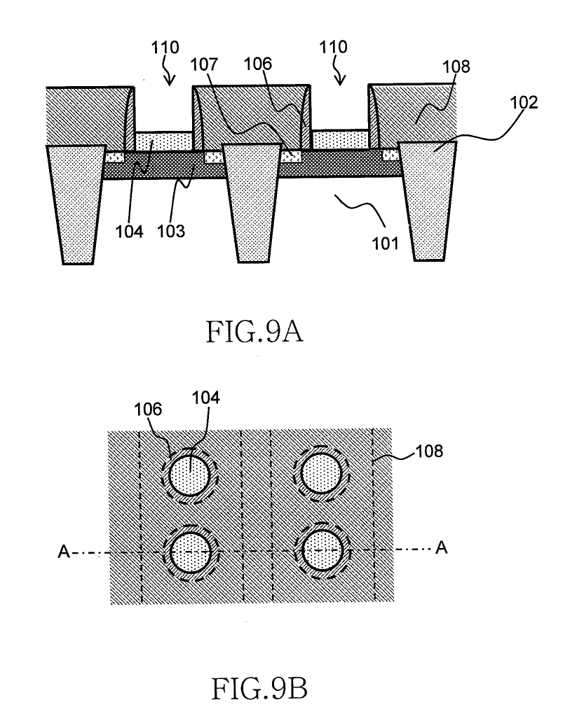

FIGS. 9A and 9B show a view showing a process (removing of the hard mask 105) in the manufacturing processes of the semiconductor memory device 10, where FIG. 9A shows a cross-sectional view, and FIG. 9B shows a plan view;

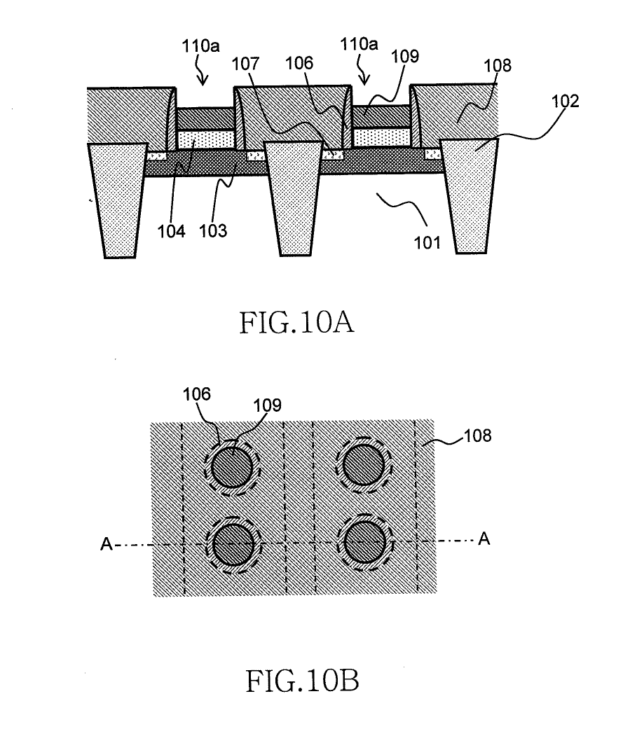

FIGS. 10A and 10B show a view showing a process (formation of contact plug 109) in the manufacturing processes of the semiconductor memory device 10, where FIG. 10A shows a cross-sectional view, and FIG. 10B shows a plan view;

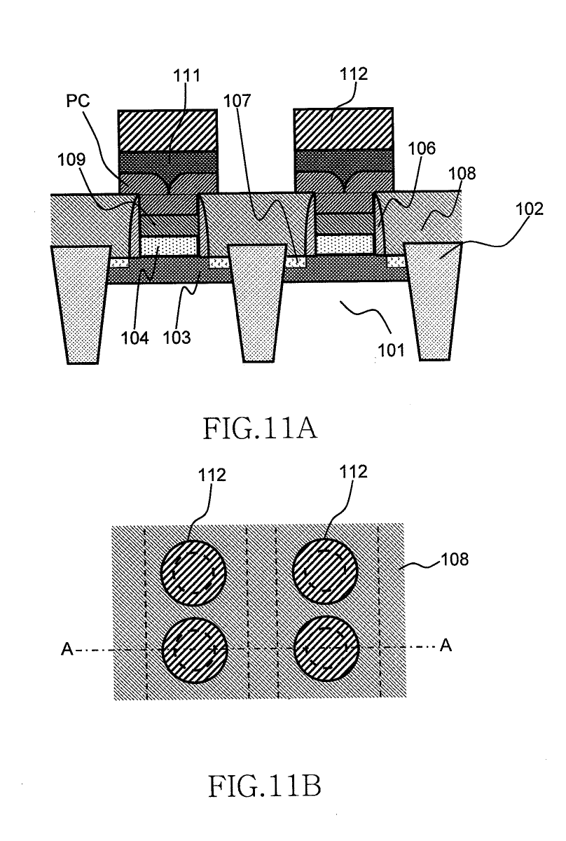

FIGS. 11A and 11B show a view showing a process (formation of a recording layer PC) in the manufacturing processes of the semiconductor memory device 10, where FIG. 11A shows a cross-sectional view, and FIG. 11B shows a plan view;

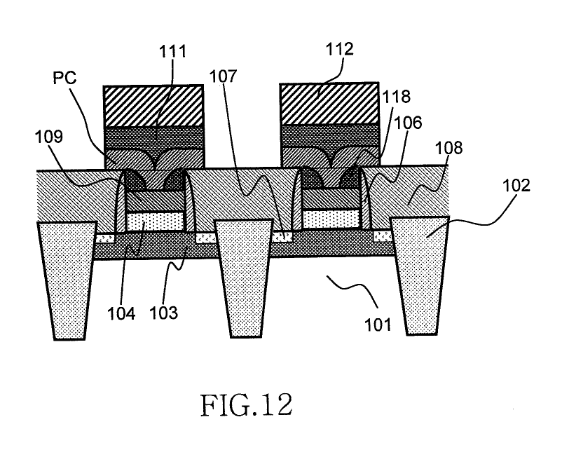

FIG. 12 is a schematic diagram showing a configuration of the memory cell MC according to a modification;

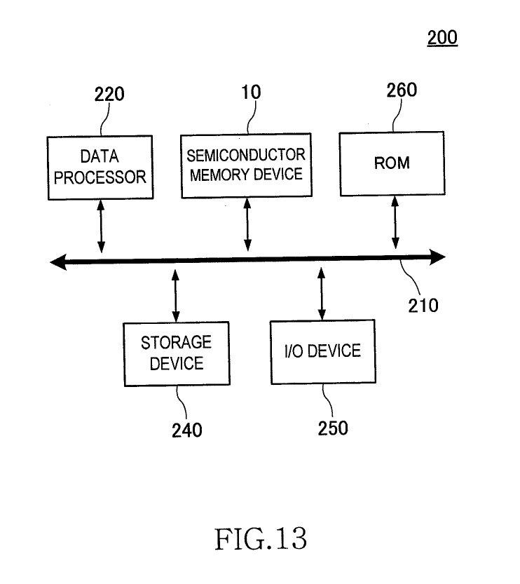

FIG. 13 is a block diagram showing a configuration of a data processing system 200 using the semiconductor memory device 1;

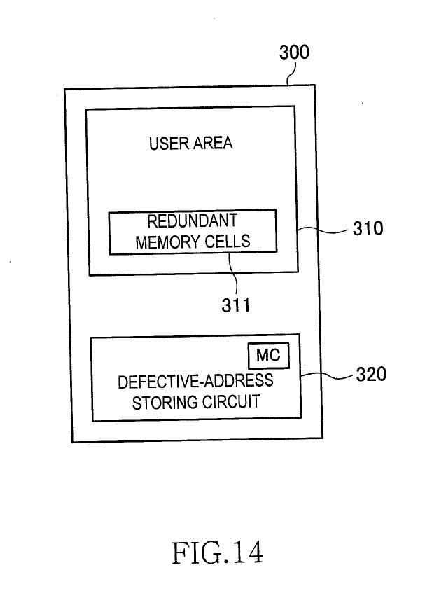

FIG. 14 is a block diagram of a semiconductor memory device 300 in which the memory cell MC according to the present invention is used for a defective-address storing circuit, for example; and

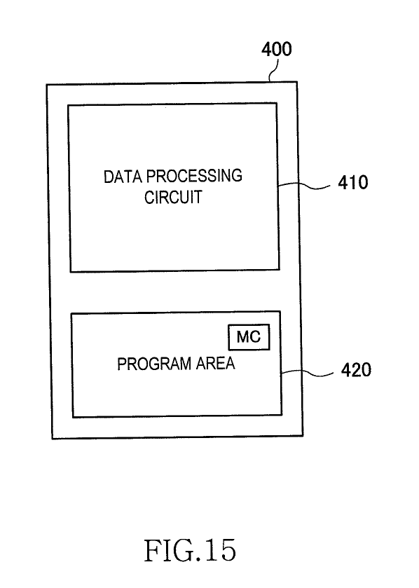

FIG. 15 is a block diagram of a data processing device 400 in which the memory cell MC according to the present invention is used in a program area, for example.

### DETAILED DESCRIPTION OF THE EMBODIMENTS

Preferred embodiments of the present invention will be explained below in detail with reference to the accompanying drawings.

FIG. 1 is a block diagram of a semiconductor memory device 10 according to an embodiment of the present invention.

The semiconductor memory device 10 according to the present embodiment is a PRAM, and can access a memory cell array 11 including many memory cells MC by inputting an address signal ADD and a command CMD from outside. That is, when the command CMD indicates a read operation, data held in the memory cell MC assigned by the address signal ADD is read out. When the command CMD indicates a write operation, write data input from outside is written in the memory cell MC assigned by the address signal ADD.

This is explained more specifically. The semiconductor memory device 10 has an address latch circuit 21 that holds the address signal ADD, and a command decoder 22 that generates an internal command ICMD by decoding the command CMD. Among the address signals ADD input to the address latch circuit 21, a row address RA is supplied to a row-system control circuit 23, and a column address CA is supplied to a column-system control circuit 24. The row-system control circuit 23 is a circuit that selects a word line WL included in the memory cell array 11, based on the row address RA and the internal command ICMD. The column-system control circuit 24 is a circuit that selects a bit line BL included in the memory cell array 11, based on the column address CA and the internal command ICMD.

The selected bit line BL is connected to a data input/output circuit 25. As a result, when the command CMD indicates a read operation, read data DQ held in the memory cell MC assigned by the address signal ADD is read out, via the data input/output circuit 25. When the command CMD indicates a write operation, write data DQ input from outside is written in the memory cell MC assigned by the address signal ADD, via the data input/output circuit 25.

FIG. 2 is a circuit diagram showing a part of the memory cell array 11 in detail.

As shown in FIG. 2, plural word lines WL are provided in the X direction, and plural bit lines BL are provided in the Y direction, in the memory cell array 11. The memory cell MC is arranged at each of intersections between the word line WL and the bit line BL. With this arrangement, plural memory cells MC are laid out in a matrix shape.

In the present embodiment, each of the word lines WL is constituted by a lower-layer word line WLa and an upper-layer word line WLb. The lower-layer word line WLa is a wiring directly connected to the memory cell MC, and is constituted by an impurity diffusion layer formed on a semiconductor substrate, as described later. On the other hand, the upper-layer word line WLb is an auxiliary wiring (a hanger word line) provided to lower the resistance of the word line WL, and is constituted by a metal wiring formed above the memory cell MC, as described later. The lower-layer word line WLa and the upper-layer word line WLb are electrically connected to each other at plural positions via contact plugs. However, it is not essential to provide the upper-layer word line WLb in the present invention.

As shown in FIG. 2, the memory cell MC is configured such that a recording layer PC as a memory element and a diode D as a selection element are connected in series. The recording layer PC and the diode D are connected in series between a corresponding word line WL (the lower-layer word line WLa) and a corresponding bit line BL.

Each recording layer PC includes a phase change compound. A phase change compound included in the recording layer PC can be any material having two or more phase states and having different electric resistances depending on a phase state. Preferably, a so-called chalcogenide compound is selected for the material. The chalcogenide compound is an alloy containing at least one of elements of germanium (Ge), antimony (Sb), tellurium (Te), indium (In), and selenium (Se). For example, the chalcogenide compound includes an element in a binary system such as GaSb, InSb, InSe, Sb₂Te₃, and GeTe, an element in a ternary system such as Ge₂Sb₂Te₅, InSbTe, GaSeTe, SnSb₂Te₄, and InSbGe, and an element in a quaternary system such as AgInSbTe, (GeSn) SbTe, GeSb (SeTe), and Te₈₁Ge₁₅Sb₂S₂.

A chalcogenide compound can take any one of an amorphous phase and a crystal phase. The chalcogenide compound becomes in a relatively high resistance state in an amorphous phase, and becomes in a relatively low resistance state in a crystal phase. The chalcogenide compound stores information by using a difference between these resistances. For example, one-bit information can be stored in one recording layer PC when a high resistance state is allocated to a logic value=0 and when a low resistance state is allocated to a logic value=1. Information of two or more bits can be stored in one recording layer PC when the resistance is controlled at many stages by adjusting a proportion between a chalcogenide compound in an amorphous state and a chalcogenide compound in a crystal state.

A phase state of a chalcogenide compound is stable without changing at a normal temperature. Therefore, information written in the recording layer PC can be held even after a power source is interrupted. Accordingly, a nonvolatile recording of information is possible. A phase state of a chalcogenide compound is reversible, and therefore information can be rewritten.

To amorphousize (reset) a phase change compound, the phase change compound is heated at a temperature equal to or higher than a melting point by passing a write current to the compound, and by rapidly cooling the compound thereafter. On the other hand, to crystallize (set) a phase change compound, the phase change compound is heated at a temperature equal to or higher than a crystallization temperature and lower than the melting point by passing a write current to the compound, and by maintaining this state for a certain period of time.

The diode D is a so-called pn-junction diode, and is formed as silicon pillars by etching the semiconductor substrate. That is, the diode D has a vertical structure. Actual configurations of the diode D and the recording layer PC are described later.

To access a desired one of the memory cells MC laid out in a matrix shape, a potential of a selected word line WL is set at 0 V, for example, and a potential of an unselected word line WL is set at 1 V, for example. Further, a potential of a selected bit line BL is set at 1 V, for example, and a potential of an unselected bit line BL is set at 0 V, for example. The row-system control circuit 23 controls a potential of the word line WL based on the row address RA shown in FIG. 1. The column-system control circuit 24 controls a potential of the bit line BL based on the column address CA shown in FIG. 1.

As a result, a forward voltage of the diode D included in the memory cell MC to be selected becomes 1 V, and becomes in an ON state because the forward voltage exceeds a threshold voltage. That is, a current flows from the bit line BL to the word line WL via the selected memory cell MC. On the other hand, a forward voltage of the diode D included in an unselected memory cell MC becomes 0 V or −1 V, and becomes in an OFF state because the forward voltage does not exceed the threshold voltage. That is, a current does not flow to a memory cell MC other than the selected memory cell MC. In this way, a current can be passed to only a desired memory cell MC.

There are three kinds of current that are passed to the memory cell MC, including a reset current, a set current, and a read current. The reset current is a current to amorphousize a phase change compound included in the recording layer PC. When the reset current is passed to the recording layer PC, the phase change compound is heated at a temperature higher than the melting point. The phase change compound is amorphousized when the phase change compound is rapidly cooled thereafter by stopping a supply of the reset current. The set current is a current to crystallize the phase change compound included in the recording layer PC. When the set current is passed to the recording layer PC, the phase change compound is heated at a temperature equal to or higher than a crystallization temperature and lower than a melting point. The phase change compound is crystallized when this state is maintained for a certain period of time or more.

On the other hand, the read current is a current to detect a phase state of a phase change compound included in the recording layer PC. The read current is set at a current sufficiently lower than the reset current or the set current.

A device configuration of the memory cell MC is explained below.

FIGS. 3A and 3B show a device configuration of the memory cell MC, where FIG. 3A shows a cross-sectional view, and FIG. 3B shows a plan view, and FIG. 3A shows a cross section along a line A-A line shown in FIG. 3B.

As shown in FIG. 3B, in the present embodiment, plural element isolation regions 102 extended to the X direction are formed on a semiconductor substrate 100, and active regions 101 defined by the element isolation regions 102 are also extended to the X direction. FIGS. 3A and 3B show three element isolation regions 102 and two active regions 101 defined by these element isolation regions 102.

On a surface of each of the active regions 101, there are formed a belt-shaped n-type impurity diffusion layer 103 extended to the X direction, and an island-shaped p-type impurity diffusion layer 104 arranged in the X direction. The n-type impurity diffusion layer 103 and the p-type impurity diffusion layer 104 area part of the semiconductor substrate 100, and the diode D is formed by a pn-junction therebetween. Therefore, the diode D has a vertical structure. A metal silicide layer 107 is formed in a region in which the p-type impurity diffusion layer 104 is not formed, on a surface of the n-type impurity diffusion layer 103. The metal silicide layer 107 functions to decrease the resistance of the n-type impurity diffusion layer 103 extended to the X direction. The n-type impurity diffusion layer 103 and the metal silicide layer 107 function as the lower-layer word line WLa. However, it is not essential to provide the metal silicide layer 107 in the present invention.

As shown in FIG. 3A, the whole of the p-type impurity diffusion layer 104 and a part of the n-type impurity diffusion layer 103 are formed in a region surrounded by a cylindrical sidewall insulation film 106. A contact plug 109 that functions as a heater electrode is formed above the p-type impurity diffusion layer 104. The contact plug 109 is also formed in a region surrounded by the cylindrical sidewall insulation film 106. Therefore, a planar position of the p-type impurity diffusion layer 104 is coincident with a planar position of the contact plug 109. At the same time, a diameter of an interface between these planar positions is coincident with an internal diameter of the cylindrical sidewall insulation film 106. Accordingly, an area of this interface can be sufficiently secured, and thus a contact resistance can be decreased. However, in the present invention, it is not essential that the whole of the p-type impurity diffusion layer 104 is formed in the region surrounded by the cylindrical sidewall insulation film 106, and it suffices that a part of the p-type impurity diffusion layer 104 is formed in the region surrounded by the cylindrical sidewall insulation film 106.

Further, the recording layer PC is formed above the contact plug 109. The recording layer PC contains a chalcogenide compound, and functions as a memory element. The recording layer PC is arranged in an island shape in the X direction. Although not shown, the recording layer PC can be provided to extend to the Y direction on an interlayer insulation film 108. A lower part of the recording layer PC is formed in a region surrounded by the cylindrical sidewall insulation film 106. Therefore, a planar position of an upper part of the contact plug 109 is coincident with a planar position of the lower part of the recording layer PC. At the same time, a diameter of an interface between these planar positions is coincident with an internal diameter of the cylindrical sidewall insulation film 106. Accordingly, an area of this interface can be sufficiently secured, and a contact resistance can be decreased.

An upper electrode 111 is provided above the recording layer PC. The upper electrode 111 is arranged in an island shape in the X direction. Although not shown, the upper electrode 111 can be also provided to extend to the Y direction in a similar manner to that of the recording layer PC. A hard mask 112 is provided above the upper electrode 111. A contact hole is provided in the hard mask 112, and a contact plug 114 is filled in the contact hole. The contact plug 114 is connected to a metal wiring 115 provided on the interlayer insulation film 113. The metal wiring 115 is used as the bit line BL, and is extended to the Y direction. Another metal wiring 117 is provided on the metal wiring 115 via an interlayer insulation film 116. The metal wiring 117 is used as the upper-layer word line WLb (a hanger word line), and is extended to the X direction.

The device configuration of the memory cell MC is as described above. As can be understood, according to the present embodiment, the p-type impurity diffusion layer 104, the contact plug 109, and the lower part of the recording layer PC are all formed in the region surrounded by the cylindrical sidewall insulation film 106. Therefore, diameter of the interface between these portions is coincident with the internal diameter of the sidewall insulation film 106. Because the area of the interface is sufficiently secured, a contact resistance can be decreased.

Further, because silicon pillars constituting the diode D are constituted by a part of the semiconductor substrate 100, a leakage current attributable to a crystal defect can be prevented different from when silicon pillars are formed by using the selective epitaxial method. The selective epitaxial method has a problem in that a growth of silicon is not necessarily uniform. When an area of a growth surface is very small, growth little progresses. On the other hand, these problems do not occur in the present embodiment.

A manufacturing method of the memory cell MC according to the present embodiment is explained next.

FIGS. 4A and 4B to FIGS. 11A and 11B are process diagrams for explaining the manufacturing method of a semiconductor memory device according to the present embodiment, where FIGS. 4 to 11 with “A” attached thereto are cross-sectional diagrams, and FIGS. 4 to 11 with “B” attached thereto are plan views. FIGS. 4 to 11 with “A” attached thereto show cross sections along a line A-A shown in FIGS. 4 to 11 with “B” attached thereto, respectively.

As shown in FIGS. 4A and 4B, the active regions 101 extended to the X direction are defined by forming the element isolation regions 102 on the semiconductor substrate 100. An STI (Shallow Trench Isolation) can be used as the element isolation region 102. The n-type impurity diffusion layer 103 and the p-type impurity diffusion layer 104 are formed in an upper region of the active region 101 by ion implanting an n-type impurity and a p-type impurity in this order. As a result, a pn-junction that becomes the diode D is formed. Next, an insulation film is formed on the whole surface, and this insulation film is patterned thereafter, to form plural hard masks 105 in an island shape arranged in the X direction on the p-type impurity diffusion layer 104. Silicon nitride is preferably used as the material of the hard masks 105.

Next, as shown in FIGS. 5A and 5B, the active regions 101 are etched using the hard masks 105. As the etching amount in this case, it is preferable that the active regions 101 are etched until when the n-type impurity diffusion layer 103 is exposed at portions not covered by the hard masks 105. As a result, silicon pillars made of a part of the semiconductor substrate 100 are formed in the active regions 101, and upper parts of the silicon pillars are constituted by the p-type impurity diffusion layer 104.

Next, as shown in FIGS. 6A and 6B, an insulation film is formed on the whole surface, and this insulation film is etched back to form the cylindrical sidewall insulation film 106 on side surfaces of the silicon pillars and the hard masks 105. It is preferable that a material different from that of the hard masks 105 is used as the material of the cylindrical sidewall insulation film 106. For example, when silicon nitride is used as the material of the hard masks 105, silicon oxide is preferably used as the material of the sidewall insulation film 106.

Next, as shown in FIGS. 7A and 7B, a metal film such as cobalt is formed on the whole surface, and the metal film is annealed to silicify in a self-aligned manner an exposed surface of the n-type impurity diffusion layer 103. As a result, the metal silicide layer 107 is formed on the surface of the n-type impurity diffusion layer 103.

Next, as shown in FIGS. 8A and 8B, the interlayer insulation film 108 is formed on the whole surface, and the interlayer insulation film 108 is polished by a CMP method using the hard mask 105 as stoppers. Therefore, a material different from that of the hard masks 105 needs to be used as the material of the interlayer insulation film 108. When silicon nitride is used as the material of the hard mask 105, for example, silicon oxide is preferably used as the material of the interlayer insulation film 108.

Next, as shown in FIGS. 9A and 9B, the hard mask 105 is removed. When the hard mask 105 is made of silicon nitride, they can be selectively removed by using thermal phosphoric acid. As a result, a cavity 110 surrounded by the sidewall insulation film 106 is formed.

A metal film such as cobalt is formed on the whole surface, and thereafter, the metal film is annealed to silicify an upper part of the p-type impurity diffusion layer 104. As shown in FIGS. 10A and 10B, a metal film (a titanium nitride film, for example) that becomes a heater is then formed on the whole surface, and thereafter, the metal film is polished by the CMP method by using the interlayer insulation film 108 as a stopper, and the contact plug 109 is embedded into each of the cavities 110. An upper surface of the contact plug 109 is etched back from an upper end of the sidewall insulation film 106, thereby forming a recess region 110a in a region surrounded by the sidewall dielectric film 106. Because a position where the contact plug 109 is formed is defined by the cylindrical sidewall insulation film 106 in this way, each of the contact plugs 109 is formed in a self-aligned manner on the p-type impurity diffusion layer 104.

Next, as shown in FIGS. 11A and 11B, the recording layer PC made of a chalcogenide compound, the upper electrode 111, and the hard mask 112 are formed in this order, and these are patterned to be arranged in an island shape in the X direction along the active region 101. Silicon oxide can be used as the material of the hard mask 112, for example. As described above, at the time of forming the recording layer PC, because the recess region 110a is formed in the region surrounded in the sidewall insulation film 106, a lower part of the recording layer PC is formed in this recess region 110a. Because a position where the lower part of the recording layer PC is formed is defined by the sidewall insulation film 106, the lower part of the recording layer PC is also formed in a self-aligned manner on the p-type impurity diffusion layer 104.

Thereafter, as shown in FIGS. 3A and 3B, the interlayer insulation film 113 is formed and this film is planarized by the CMP method. An opening is then provided in the hard mask 112 by the photolithography method. The metal wiring 115 that becomes the bit line BL is formed after the contact plug 114 made of a metal such as tungsten has been embedded in the opening. The metal wiring 117 that becomes the upper-layer word line WLb is then formed via the interlayer insulation film 116, thereby completing the memory cell MC.

As explained above, according to the manufacturing method of the present embodiment, because the contact plug 109 and the lower part of the recording layer PC are formed in a self-aligned manner on the p-type impurity diffusion layer 104, there occurs no deviation in alignment between these parts. Because, securing a margin by taking into account a deviation in alignment is not necessary, the degree of integration can be increased more.

FIG. 12 is a schematic diagram showing a configuration of the memory cell MC according to a modification.

The memory cell MC shown in FIG. 12 is different from the memory cell MC shown in FIG. 3A in that a sidewall insulation film 118 is provided above the contact plug 109. Other features of the memory cell MC is identical to those of the memory cell MC shown in FIG. 3A, and thus like elements are denoted by like reference characters and explanations thereof will be omitted.

The sidewall insulation film 118 is formed in a region surrounded by the sidewall insulation film 106, and functions to reduce a contact area between the contact plug 109 and the recording layer PC. When the contact area between the contact plug 109 and the recording layer PC is reduced, a current flowing to the recording layer PC is concentrated. Therefore, it becomes possible to reduce a current necessary for a reset operation and a set operation. As a result, power consumption can be reduced.

The sidewall insulation film 118 can be formed by forming an insulation film on the whole surface of the contact plug 109 after forming the contact plug 109, and by etching back the insulation film. Therefore, it is preferable that a material different from that of the interlayer insulation film 108 is used as the material of the sidewall insulation film 118. Specifically, when the interlayer insulation film 108 is made of silicon oxide, silicon nitride is preferably used as the material of the sidewall insulation film 118.

FIG. 13 is a block diagram showing a configuration of a data processing system 200 using the semiconductor memory device 10 according to the present embodiment.

The data processing system 200 shown in FIG. 13 is configured such that a data processor 220 and the semiconductor memory device 10 shown in FIG. 1 are connected to each other via a system bus 210. For example, a microprocessor (MPU) and a digital signal processor (DSP) are mentioned as the data processor 220, but are not limited thereto. To simplify the drawing, in FIG. 13, the data processor 220 and the semiconductor memory device 10 are connected to each other via the system bus 210. Alternatively, the data processor 220 and the semiconductor memory device 10 can be connected to each other via a local bus without using the system bus 210.

To simplify the drawing, FIG. 13 shows only one set of the system bus 210. However, the system bus 210 can be also provided in series or in parallel via connectors or the like, when necessary. In the data processing system 200 shown in FIG. 13, a storage device 240, an I/O device 250, and a ROM 260 are connected to the system bus 210, but these are not necessarily essential constituent elements.

A hard disk drive, an optical disk drive, and a flash memory are mentioned as the storage device 240. A display device such as a liquid crystal display, and an input device such as a keyboard and a mouse are mentioned as the I/O device 250. The I/O device 250 can be only one of an input device and an output device. To simplify the drawing, respective constituent elements is shown as one each in FIG. 13, but the number of each of these constituent elements is not limited to one, and can be two or more.

FIG. 14 is a block diagram of a semiconductor memory device 300 in which the memory cell MC according to the present invention is used for a defective-address storing circuit, for example.

In the semiconductor memory device 300 shown in FIG. 14, the memory cell MC according to the present invention is not used in a user area 310, but is used in a defective-address storing circuit 320 that stores a defective address included in the user area 310. The user area 310 is a region that is rewritable by a user. A DRAM cell, an SRAM cell, and a flash memory cell are mentioned as the memory cell. A defective address is sometimes found in these memory cells at a manufacturing state. A memory cell corresponding to a detected defective address is replaced by a redundant memory cell 311, thereby relieving the defective address. The defective-address storing circuit 320 stores this defective address. In the example shown in FIG. 14, the memory cell MC according to the present invention is used for a memory cell constituting the defective-address storing circuit 320. As explained above, the memory cell MC according to the present invention can be also used as a memory cell other that in the user area 310.

FIG. 15 is a block diagram of a data processing device 400 in which the memory cell MC according to the present invention is used in a program area, for example.

The data processing device 400 shown in FIG. 15 includes a program area 420 provided in relation to a data processing circuit 410 such as a CPU, and a data processing circuit 410 performs a predetermined operation based on a program held in the program area 420. In the data processing device 400 shown in FIG. 15, the memory cell MC according to the present invention is used for a memory cell constituting the program area 420. As explained above, the memory cell MC according to the present invention can be also used as a memory cell included in a device other than the memory device.

It is apparent that the present invention is not limited to the above embodiments, but may be modified and changed without departing from the scope and spirit of the invention.

In the memory cell MC according the above embodiment, the diode D is connected to a word line WL side, and the recording layer PC is connected to a bit line BL side. However, these connecting positions can be opposite to each other. In the diode D according to the above embodiment, the bit line BL side is an anode, and the word line WL side is a cathode; however, these can be opposite to each other.

In the above embodiment, the contact plug 109 is provided between a pn-junction diode and the recording layer PC. However, the provision of the contact plug 109 is not essential in the present invention. Therefore, the pn-j unction and the recording layer PC can be directly contacted to each other.

In the above embodiment, although a phase change material containing a chalcogenide compound is used as a memory element, in the present invention, the kind of a memory element is not particularly limited. However, because a diode is used as a selection element in the semiconductor memory device, it is preferable to use a current-sensing memory element. For the current-sensing memory element, it is preferable to use a recording layer, such as a PRAM and an RRAM, in which an electric resistance can be reversibly changed.

What is claimed is:

1. A semiconductor memory device comprising:
a silicon pillar that projects to a perpendicular direction that is substantially perpendicular to a main surface of a semiconductor substrate;
a diode having first and second impurity diffusion layers which form pn-junction, the first and second impurity diffusion layers being arranged in the perpendicular direction, at least one of the first and second impurity diffusion layers being provided in the silicon pillar;
a cylindrical insulation film that surrounds a side surface of the silicon pillar and projects to the perpendicular direction, a top end of the cylindrical insulation film is higher than that of the silicon pillar; and
a memory element electrically connected to the first impurity diffusion layer in a surrounded region that is surrounded by the cylindrical insulation film.

2. The semiconductor memory device as claimed in claim 1, further comprising a contact plug that is formed in the surrounded region and electrically connects the first impurity diffusion layer and the memory element to each other.

3. The semiconductor memory device as claimed in claim 2, wherein a diameter of an interface between the first impurity diffusion layer and the contact plug is coincident with an internal diameter of the cylindrical insulation film.

4. The semiconductor memory device as claimed in claim 2, wherein a diameter of an interface between the contact plug and the memory element is coincident with an internal diameter of the cylindrical insulation film.

5. The semiconductor memory device as claimed in claim 1, wherein whole of the first impurity diffusion layer and a part of the second impurity diffusion layer are provided in the silicon pillar.

6. The semiconductor memory device as claimed in claim 1, further comprising a first signal wiring extending to a first direction in parallel to the main surface of the semiconductor substrate and electrically connected to the memory element, wherein
the second impurity diffusion layer extends to a second direction that intersect with the first direction and parallel to the main surface of the semiconductor substrate

7. The semiconductor memory device as claimed in claim 6, further comprising a second signal wiring extending to the second direction, wherein
the second impurity diffusion layer and the second signal wiring are electrically connected to each other at plural positions.

8. The semiconductor memory device as claimed in claim 6, wherein a portion not covered with the cylindrical insulation film out of a surface of the second impurity diffusion layer is silicified.

9. The semiconductor memory device as claimed in claim 1, wherein the memory element includes a recording layer in which an electric resistance can be reversibly changed.

10. The semiconductor memory device as claimed in claim 9, wherein the recording layer contains a phase change material.

11. A semiconductor memory device comprising:
a pn-junction diode having first and second impurity diffusion layers that are apart of a semiconductor substrate, one of the first and second impurity diffusion layers functions as an anode of the pn-junction diode, other of the first and second impurity diffusion layers functions as a cathode of the pn-junction diode;
a memory element electrically connected to the first impurity diffusion layer; and
a cylindrical insulation film provided on the second impurity diffusion layer, wherein
at least a part of the first impurity diffusion layer and at least apart of the memory element are formed in a region surrounded by the cylindrical insulation film.

12. A semiconductor memory device comprising:
a plurality of first impurity diffusion layers arranged in a matrix in first and second directions;
a plurality of second impurity diffusion layers in a line shape extending to the second direction, each of the second impurity diffusion layers being provided at a lower part of the first impurity diffusion layers arranged in the second direction so as to form pn-junctions;
a plurality of memory elements arranged in a matrix in the first and second directions, and provided at an upper part of the first impurity diffusion layers, each of the memory elements being electrically connected to a corresponding one of the first impurity diffusion layers; and
a plurality of bit lines in a line shape extending to the first direction, and electrically connected in common to the memory elements arranged in the first direction, wherein
the first and second impurity diffusion layers are a part of a semiconductor substrate, and
each of the memory elements is formed in a self-aligned manner with respect to a corresponding one of the first impurity diffusion layers.

13. The semiconductor memory device as claimed in claim 12, further comprising a plurality of contact plugs that are arranged in a matrix in the first and second directions, wherein
each of the contact plugs electrically connects a corresponding one of the first impurity diffusion layers and a corresponding one of the memory elements to each other, and
each of the contact plugs is formed in a self-aligned manner with respect to a corresponding one of the first impurity diffusion layers.

14. The semiconductor memory device as claimed in claim 13, wherein each diameter of an interface between the first impurity diffusion layers and the contact plugs is coincident with each diameter of an interface between the contact plugs and the memory elements.

15. The semiconductor memory device as claimed in claim 12, wherein the memory element includes a recording layer in which an electric resistance can be reversibly changed.

16. The semiconductor memory device as claimed in claim 15, wherein the recording layer contains a phase change material.

17. A manufacturing method of a semiconductor memory device, comprising:
forming a diode having a pn-junction by forming a first impurity diffusion layer in a semiconductor substrate and forming a second impurity diffusion layer at a lower part of the first impurity diffusion layer, thereby the first and second impurity diffusion layers are arranged in a direction perpendicular to a main surface of the semiconductor substrate;
patterning the first impurity diffusion layer using a hard mask to form a silicon pillar;
forming a sidewall insulation film on a side surface of the silicon pillar and the hard mask;
removing the hard mask to form a cavity in a region surrounded by the sidewall insulation film; and
forming at least a part of the memory element in the cavity.

18. The manufacturing method of a semiconductor memory device as claimed in claim 17, further comprising forming a contact plug in the cavity, after removing the hard mask and before forming at least the part of the memory element.

19. The manufacturing method of a semiconductor memory device as claimed in claim 17, wherein patterning the first impurity diffusion layer is performed until when the second impurity diffusion layer is exposed.

20. The manufacturing method of a semiconductor memory device as claimed in claim 19, further comprising forming a metal silicide by forming a metal film on a surface of the second impurity diffusion layer and annealing the metal film thereafter, after forming the sidewall insulation film and before removing the hard mask.

21. The manufacturing method of a semiconductor memory device as claimed in claim 17, wherein forming at least the part of the memory element is performed by forming a chalcogenide material in the cavity, and by patterning the chalcogenide material thereafter.

22. A data processing system comprising:
a semiconductor memory device;
a data processor; and
a system bus that connects the semiconductor memory device and the data processor to each other,
wherein a memory cell included in the semiconductor memory device comprises:
a silicon pillar that projects to a perpendicular direction that is substantially perpendicular to a main surface of a semiconductor substrate;
a diode having first and second impurity diffusion layers which form pn-junction, the first and second impurity diffusion layers being arranged in the perpendicular direction, at least one of the first and second impurity diffusion layers being provided in the silicon pillar;
a cylindrical insulation film that surrounds a side surface of the silicon pillar and projects to the perpendicular direction, a top end of the cylindrical insulation film is higher than that of the silicon pillar; and
a memory element electrically connected to the first impurity diffusion layer in a surrounded region that is surrounded by the cylindrical insulation film.

23. A semiconductor memory device comprising:
a data rewritable user area; and
a defective-address storing circuit that stores a defective address included in the user area,
wherein a memory cell included in the defective-address storing circuit comprises:
a silicon pillar that projects to a perpendicular direction that is substantially perpendicular to a main surface of a semiconductor substrate;
a diode having first and second impurity diffusion layers which form pn-junction, the first and second impurity diffusion layers being arranged in the perpendicular direction, at least one of the first and second impurity diffusion layers being provided in the silicon pillar;
a cylindrical insulation film that surrounds a side surface of the silicon pillar and projects to the perpendicular direction, a top end of the cylindrical insulation film is higher than that of the silicon pillar; and
a memory element electrically connected to the first impurity diffusion layer in a surrounded region that is surrounded by the cylindrical insulation film.

24. A data processing device comprising:
a program area; and
a data processing circuit that performs a predetermined operation in accordance with a program stored in the program area,
wherein a memory cell included in the program area comprises:
a silicon pillar that projects to a perpendicular direction that is substantially perpendicular to a main surface of a semiconductor substrate;
a diode having first and second impurity diffusion layers which form pn-junction, the first and second impurity diffusion layers being arranged in the perpendicular direction, at least one of the first and second impurity diffusion layers being provided in the silicon pillar;
a cylindrical insulation film that surrounds a side surface of the silicon pillar and projects to the perpendicular direction, a top end of the cylindrical insulation film is higher than that of the silicon pillar; and
a memory element electrically connected to the first impurity diffusion layer in a surrounded region that is surrounded by the cylindrical insulation film.
